(19) United States
(12) Patent Application Publication
(10) Pub. No.: US 2024/0145427 A1
(43) Pub. Date: May 2, 2024

(54) APPARATUS CONFIGURED TO TRANSFER ELECTRONIC COMPONENT, METHOD FOR BONDING ELECTRONIC COMPONENT, AND METHOD FOR MANUFACTURING LIGHT-EMITTING DIODE DISPLAY

(71) Applicant: Stroke Precision Advanced Engineering Co., Ltd., Taoyuan City (TW)

(72) Inventor: Chingju Lin, Taoyuan City (TW)

(73) Assignee: Stroke Precision Advanced Engineering Co., Ltd., Taoyuan City (TW)

(21) Appl. No.: 18/450,429

(22) Filed: Aug. 16, 2023

(30) Foreign Application Priority Data
Oct. 26, 2022 (TW) 111140560

(51) Int. Cl. H01L 23/00; H01L 25/16

(52) U.S. Cl. CPC H01L 24/75; H01L 24/81; H01L 25/167; H01L 24/16; H01L 2224/16145; H01L 2224/75263; H01L 2224/75314; H01L 2224/7555; H01L 2224/81005; H01L 2224/81201; H01L 2224/81224; H01L 2924/12041

(57) ABSTRACT

An apparatus configured to transfer an electronic component, including a first carrier, a second carrier, an actuator mechanism, and a flexible push generator, is provided. The first carrier is configured to carry a target substrate. The second carrier is configured to carry a transfer substrate. The actuator mechanism is configured to actuate the first and second carriers to move close to and away from each other. The flexible push generator generates a flexible push to the carried target substrate or transfer substrate when the first and second carriers move close to each other. When the flexible push is starting to be generated, a flexible push generated on a central area of the target substrate or the transfer substrate is greater than that on a surrounding area. A method for bonding an electronic component and a method for manufacturing a light-emitting diode display are also provided.

### CROSS-REFERENCE TO RELATED APPLICATION

This application claims the priority benefit of Taiwan application serial no. 111140560, filed on Oct. 26, 2022. The entirety of the above-mentioned patent application is hereby incorporated by reference herein and made a part of this specification.

### BACKGROUND

### Technical Field

The disclosure relates to an apparatus configured to transfer an electronic component, a method for bonding an electronic component, and a method for manufacturing a light-emitting diode display.

### Description of Related Art

The semiconductor component is usually grown on a growth substrate by means of epitaxy. However, as the various applications of the semiconductor component change, the semiconductor component may not stay on the original growth substrate when finally finished, but may be transferred to a transfer substrate, and finally transferred to a target substrate to form a final product.

When transferring the semiconductor component from the transfer substrate to the target substrate, there is a method to let the front surfaces of the transfer substrate and the target substrate face each other, and press the transfer substrate and the target substrate. The conventional pressing manner is to align the transfer substrate and the target substrate using a mechanism and then press directly, so that the planes of the two substrates are in full contact. However, when the transfer substrate is placed on the target substrate, there may easily be residual air bubbles between the surfaces where the transfer substrate and the target substrate are attached to each other, thereby affecting the yield of the final product.

### SUMMARY

The disclosure provides an apparatus configured to transfer an electronic component, which can effectively remove residual air bubbles between a target substrate and a transfer substrate, thereby improving the process yield.

The disclosure provides a method for bonding an electronic component, which can effectively remove residual air bubbles between a target substrate and a transfer substrate, thereby improving the process yield.

The disclosure provides a method for manufacturing a light-emitting diode display, which has a relatively high yield.

An embodiment of the disclosure provides an apparatus configured to transfer an electronic component. The apparatus includes a first carrier, a second carrier, an actuator mechanism, and a flexible push generator. The first carrier is configured to carry a target substrate. The second carrier is configured to carry a transfer substrate. The actuator mechanism is configured to actuate the first carrier and the second carrier to move close to and away from each other. The flexible push generator is disposed near the first carrier or the second carrier and applying a flexible push to the target substrate or the transfer substrate when the first carrier and the second carrier move close to each other, wherein the flexible push is in a greater magnitude onto a central portion of the target substrate or of the transfer substrate than onto a peripheral portion of the target substrate or of the transfer substrate at the start of the flexible push being applied.

In an embodiment of the disclosure, the flexible push generator includes an inflator and an air bag connected to the inflator, and the inflator inflates the air bag.

In an embodiment of the disclosure, the apparatus configured to transfer an electronic component further includes a laser generator, disposed near the first carrier or the second carrier and generating a laser beam toward the first carrier or the second carrier.

An embodiment of the disclosure provides a method for bonding an electronic component, including: providing a transfer substrate having a carrying surface on which the electronic component to be bonded is disposed and a non-carrying surface which is opposite to the carrying surface; providing a target substrate having a bonded surface and a non-bonded surface which is opposite to the bonded surface; arranging the carrying surface of the transfer substrate to face the bonded surface of the target substrate; making the transfer substrate and the target substrate approach each other until the electronic component is in contact with the bonded surface of the target substrate; applying a flexible push to the non-carrying surface of the transfer substrate or to the non-bonded surface of the target substrate, wherein the flexible push is in a greater magnitude onto a central portion of the non-carrying surface or of the non-bonded surface than onto a peripheral portion of the non-carrying surface or of the non-bonded surface at the start of the flexible push being applied; and applying an energy beam to bond the electronic component on the bonded surface of the target substrate from the transfer substrate.

In an embodiment of the disclosure, the flexible push reaches a universal magnitude gradually from the central portion to the peripheral portion of the non-carrying surface or of the non-bonded surface.

In an embodiment of the disclosure, the flexible push is generated by inflating an air bag.

In an embodiment of the disclosure, the energy beam is a laser beam.

In an embodiment of the disclosure, the electronic component is a light-emitting diode.

In an embodiment of the disclosure, the target substrate is a thin film transistor substrate.

An embodiment of the disclosure provides a method for manufacturing a light-emitting diode display, including bonding a light-emitting diode using the aforementioned method for bonding an electronic component.

In the apparatus configured to transfer an electronic component, the method for bonding an electronic component, and the method for manufacturing a light-emitting diode display according to the embodiments of the disclosure, when the flexible push is starting to be generated, the flexible push generated on the central area of the target substrate or the transfer substrate is greater than the flexible push generated on the surrounding area, so the residual air bubbles between the target substrate and the transfer substrate are pushed toward the edge of the target substrate or the transfer substrate, and then discharged from the edge. Therefore, the apparatus configured to transfer an electronic component, the method for bonding an electronic component, and the method for manufacturing a light-emitting diode display according to the embodiments of the disclosure can effectively remove the residual air bubbles between the target substrate and the transfer substrate, thereby improving the process yield.

### BRIEF DESCRIPTION OF THE DRAWINGS

FIG. 1 is a schematic perspective view of an apparatus configured to transfer an electronic component according to an embodiment of the disclosure.

FIG. 2A to FIG. 2E are schematic cross-sectional views of an apparatus configured to transfer an electronic component in five different operating stages according to another embodiment of the disclosure.

FIG. 3A to FIG. 3E are schematic cross-sectional views of an apparatus configured to transfer an electronic component in five different operating stages according to yet another embodiment of the disclosure.

### DESCRIPTION OF THE EMBODIMENTS

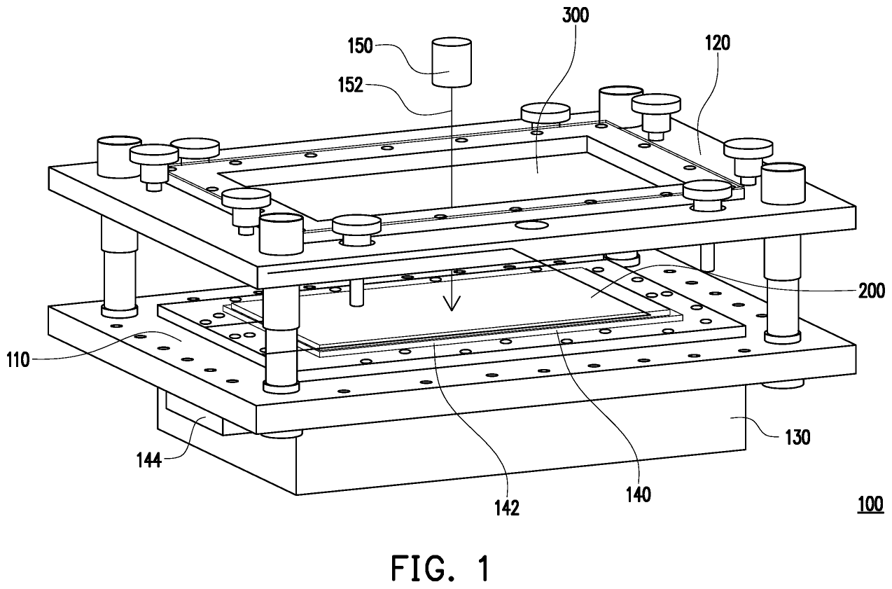

FIG. 1 is a schematic perspective view of an apparatus configured to transfer an electronic component according to an embodiment of the disclosure. Please refer to FIG. 1. An apparatus 100 configured to transfer an electronic component of this embodiment includes a first carrier 110, a second carrier 120, an actuator mechanism 130, and a flexible push generator 140. The first carrier 110 is configured to carry a target substrate 200, and the second carrier 120 is configured to carry a transfer substrate 300. The actuator mechanism 130 is configured to actuate the first carrier 110 and the second carrier 120 to move close to and away from each other. The actuator mechanism 130 is, for example, a motor, a bolt, other actuator mechanisms, or a combination thereof. The flexible push generator 140 is disposed near the first carrier 110 or the second carrier 120 (FIG. 1 is exemplified by being near the first carrier 110). The flexible push generator 140 may generate a flexible push on the carried target substrate 200 or transfer substrate 300 (FIG. 1 is exemplified by generating the flexible push to the target substrate 200) when the first carrier 110 and the second carrier 120 move closer to each other.

In this embodiment, the flexible push generator 140 includes an air-filled airbag. The flexible push generator 140 includes an air bag 142. The air bag 142 is connected to an inflator 144 (or an air suction mechanism), and the inflator 144 may inflate the air bag 142. When the first carrier 110 and the second carrier 120 move close to each other, the inflator 144 inflates the air bag 142. The inflator 144 (or the air suction mechanism) is, for example, an air pump (or an air suction pump) or other devices with an inflation function (or other devices with an air suction function). When the inflator 144 inflates the air bag 142 to start to generate a flexible push, the flexible push generated on a central portion of the target substrate 200 or the transfer substrate 300 (FIG. 1 is exemplified by the target substrate 200) is greater than the flexible push generated on a peripheral portion. In this way, the residual air bubbles between the target substrate 200 and the transfer substrate 300 are pushed toward the edge of the target substrate 200 or the transfer substrate 300, and then discharged from the edge. Therefore, the apparatus 100 configured to transfer an electronic component of this embodiment can effectively remove the residual air bubbles between the target substrate 200 and the transfer substrate 300, thereby improving the process yield. Also, as the inflator 144 continues to inflate, the flexible push generated on the central portion of the target substrate 200 or the transfer substrate 300 (FIG. 1 is exemplified by the target substrate 200) gradually becomes consistent with the flexible push generated on the peripheral portion, so that the target substrate 200 and the transfer substrate 300 are evenly pressed. The process of the flexible push will be described in more detail with drawings in the next and next embodiments.

In this embodiment, the apparatus 100 configured to transfer an electronic component further includes a laser generator 150, which is disposed adjacent to the first carrier 110 or the second carrier 120 (FIG. 1 is exemplified by being adjacent to the second carrier 120) and may generate a laser beam 152 on the carried target substrate 200 and/or transfer substrate 300. In this embodiment, the laser generator 150 is a laser light source, and the laser beam 152 is, for example, an infrared laser beam, but the disclosure is not limited thereto. In other embodiments, the laser beam 152 may also be a visible laser beam or an ultraviolet laser beam.

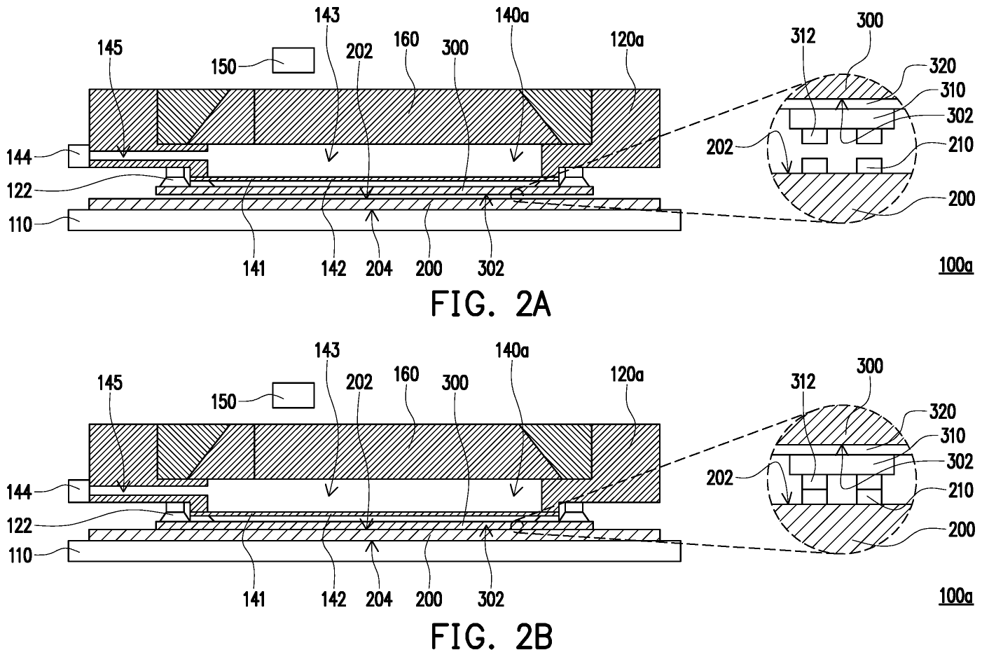

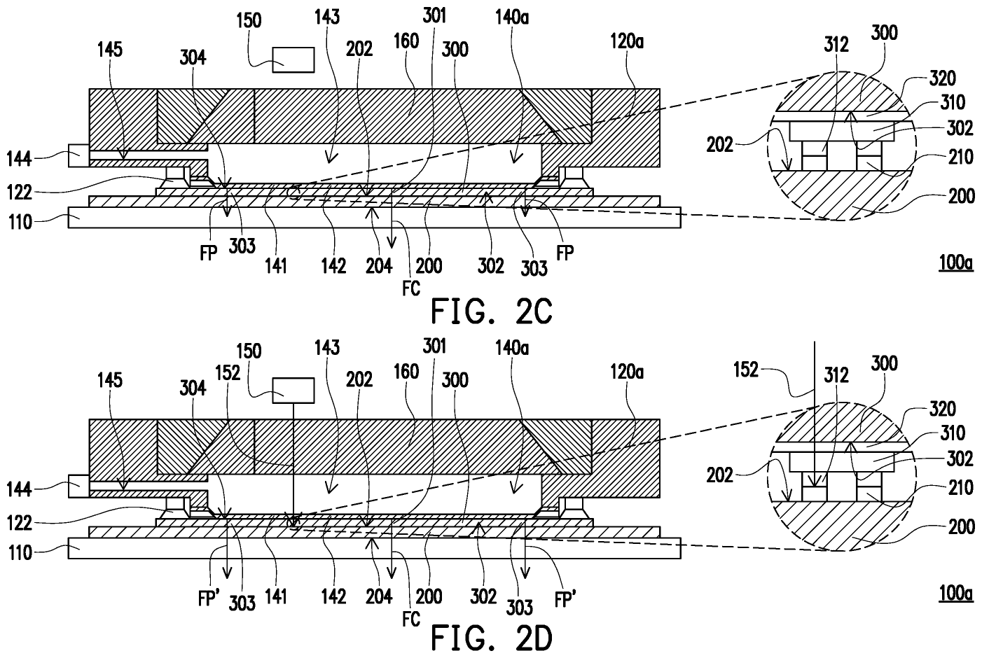

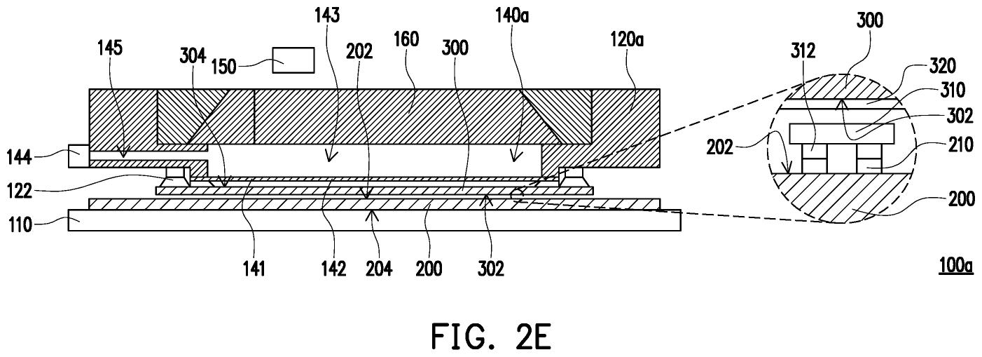

FIG. 2A to FIG. 2E are schematic cross-sectional views of an apparatus configured to transfer an electronic component in five different operating stages according to another embodiment of the disclosure. Please refer to FIG. 2A, an apparatus 100a configured to transfer an electronic component of this embodiment is similar to the apparatus 100 configured to transfer an electronic component of FIG. 1, and the differences between the two are as follows. A flexible push generator 140a of the apparatus 100a configured to transfer an electronic component of this embodiment is disposed adjacent to a second carrier 120a. A transparent cover 160 (for example, a quartz cover, but the disclosure is not limited thereto) is disposed on the second carrier 120a, an elastic film 141 is disposed below the second carrier 120a, and a space between the elastic film 141, the transparent cover 160, and the second carrier 120a forms a pressure chamber 143 in the air bag 142. The pressure chamber 143 is communicated with the inflator 144 through an air channel 145.

The apparatus 100a configured to transfer an electronic component of this embodiment and the apparatus 100 configured to transfer an electronic component of the foregoing embodiment may both be configured to execute a method for bonding an electronic component of an embodiment of the disclosure. The following description is exemplified by the apparatus 100a configured to transfer an electronic component. The method for bonding an electronic component of this embodiment includes the following steps. First, please refer to FIG. 2A. The transfer substrate 300 is provided, and at least one electronic component 310 (for example, multiple electronic components 310 in this embodiment, and one electronic component 310 is shown in the partially enlarged drawing of FIG. 2A) is disposed on a surface thereof. In addition, the target substrate 200 is provided and has a bonded surface 202 and a non-bonded surface 204, wherein multiple bumps 210 corresponding to the electronic component 310 may be disposed on the bonded surface 202. On the other hand, the first carrier 110 carries the target substrate 200, and the second carrier 120a may suck the transfer substrate 300 through a suction nozzle 122. In this embodiment, the transfer substrate 300 is a transparent substrate through which the laser beam 152 may penetrate, such as a glass substrate, and the electronic component 310 is fixed onto the transfer substrate 300 through an adhesion layer 320. A chip of the electronic component 310 may be manufactured on a growth substrate by an epitaxy process. After manufacturing, the electronic component 310 is transferred from the growth substrate to the transfer substrate 300, and the electronic component 310 is fixed onto the transfer substrate 300 through the adhesion layer 320. In this embodiment, the electronic component 310 is a light-emitting diode, such as a light-emitting diode chip, but the disclosure is not limited thereto. In other embodiments, the electronic component 310 may also be other chips. In this embodiment, the target substrate 200 is a thin film transistor substrate. However, in other embodiments, the target substrate 200 may also be other types of substrates, such as a silicon substrate and a circuit board, but the disclosure is not limited thereto. For example, a substrate made of a material less likely to absorb the laser beam 152 is a preferred choice.

In the step of FIG. 2A, the transfer substrate 300 may be aligned with the target substrate 200, and a gap may be maintained between the two. For example, a pad 312 of the electronic component 310 on the transfer substrate 300 may be aligned with the bump 210 on the target substrate 200.

Next, as shown in FIG. 2B, a surface (that is, a surface 302) of the transfer substrate 300 provided with the electronic component 310 faces the bonding surface 202 of the target substrate 200, and the transfer substrate 300 and the target substrate 200 approach each other until the electronic component 310 abuts against the bonding surface 202 of the target substrate 200. For example, the pad 312 on the electronic component 310 abuts against the bump 210 on the bonding surface 202. For example, the transfer substrate 300 may be placed on the target substrate 200, and one side of the transfer substrate 300 may contact the target substrate 200 first, and the other side of the transfer substrate 300 may then contact the target substrate 200. Or, each side of the transfer substrate 300 may be lowered together to contact the target substrate 200 at the same time.

Afterwards, as shown in FIG. 2C, a flexible push is applied on a surface (that is, a surface 304) of the transfer substrate 300 not provided with the electronic component 310 or the non-bonding surface 204 of the target substrate 200, and FIG. 2C is exemplified by applying the flexible push to the surface 304 of the transfer substrate 300. In this embodiment, the inflator 144 may be used to inflate the pressure chamber 143, so that the air bag 142 expands, that is, the elastic film 141 deforms downward to press the transfer substrate 300, and the elastic film 141 applies the flexible push on the transfer substrate 300. In other words, the flexible push is generated by inflating the air bag 142 to push the surface (that is, the surface 304) of the transfer substrate 300 not provided with the electronic component 310 or the non-bonding surface 204 of the target substrate 200.

When the inflator 144 inflates the air bag 142 to start to generate the flexible push, a flexible push FC generated on a central portion 301 of the target substrate 200 or the transfer substrate 300 (FIG. 2C is exemplified by the transfer substrate 300) is greater than a flexible push FP generated on a peripheral portion 303, that is, the flexible push FC generated on the central area 301 of the surface (that is, the surface 304) of the transfer substrate 300 not provided with the electronic component 310 or the non-bonding surface 204 of the target substrate 200 is greater than the flexible push FP generated on the surrounding area 303. In this way, the residual air bubbles between the target substrate 200 and the transfer substrate 300 are pushed toward the edge of the target substrate 200 or the transfer substrate 300, and then discharged from the edge. Therefore, the apparatus 100a configured to transfer an electronic component and the method for bonding an electronic component of this embodiment can effectively remove the residual air bubbles between the surface (that is, the surface 302) of the transfer substrate 300 provided with the electronic component 310 and the bonding surface 202 of the target substrate 200, thereby improving the process yield.

As the inflator 144 continues to inflate, as shown in FIG. 2D, the flexible push FC generated on the central area 301 of the target substrate 200 or the transfer substrate 300 (FIG. 2D is exemplified by the transfer substrate 300) gradually becomes consistent with a flexible push FP′ generated on the surrounding area 303, so that the target substrate 200 and the transfer substrate 300 are evenly pressed. At this time, an energy beam (for example, the laser beam 152) may be applied on the electronic component 310, so that the electronic component 310 is detached from the transfer substrate 300 and bonded on the bonding surface 202 of the target substrate 200. In this embodiment, the laser generator 150 may be used to apply the laser beam 152 on the pad 312 of the electronic component 310 and the bump 210, so that the bump 210 is in a molten state to be then bonded together with the pad 312. In this embodiment, the laser generator 150 may enable the laser beam 152 to perform linear scanning or surface scanning, so as to scan different electronic components 310, or the laser generator 150 may also enable fixed-point emission of the laser beam 152 at a specific position, so as to accurately emit laser beam 152 toward multiple different electronic components 310 at different times. In other embodiments, the energy beam may also be a non-laser beam, such as a beam converging on the electronic component 310. In this embodiment, the elastic film 141 is, for example, a silicone film, which is resistant to the laser beam 152 and may be penetrated by the laser beam 152 without being burnt.

Next, as shown in FIG. 2E, some air in the air bag 142 is discharged to release the air pressure in the pressure chamber 143, so that the elastic film 141 returns to the original shape. On the other hand, the second carrier 120a moves away from the first carrier 110. At this time, since the bonding force between the pad 312 and the bump 210 is greater than the adhesive force of the adhesion layer 320 to the electronic component 310, the electronic component 310 is separated from the adhesion layer 320 and detached from the transfer substrate 300, and is fixed onto the target substrate 200 by the bump 210. A thin film transistor circuit on the target substrate 200 may be electrically connected to the bump 210. Therefore, after the step of FIG. 2D, the target substrate 200 and the electronic component 310 thereon may form a light-emitting diode display, wherein multiple electronic components 310 are arranged in an array on the target substrate 200 to become pixels of the target substrate 200. Therefore, in this embodiment, the method for bonding an electronic component shown in FIG. 2A to FIG. 2D may be regarded as a method for manufacturing a light-emitting diode display.

In another embodiment, in the step of FIG. 2D, the laser beam 152 may be further applied on the adhesion layer 320, so that the adhesive force of the adhesion layer 320 to the electronic component 310 is removed, which makes it easier for the electronic component 310 to be detached from the adhesion layer 320 in the step of FIG. 2E.

In addition, after the electronic component 310 is separated from the adhesion layer 320 and detached from the transfer substrate 300, the transfer substrate 300 may be unloaded from the second carrier 120a. Then, the second carrier 120a is loaded with another transfer substrate 300 provided with the electronic component 310. Then, the second carrier 120a may move to other areas of the target substrate 200 not provided with the electronic component 310, thereby transferring the electronic component 310 to the entire target substrate 200 gradually area by area. However, in another embodiment, it is also possible that the amount of the electronic components 310 on one transfer substrate 300 is equal to the amount of the electronic components 310 required by the entire target substrate 200. In this case, only one transfer is required to provide all the electronic components 310 required by the target substrate 200.

In the apparatuses 100 and 100a configured to transfer an electronic component and the method for bonding an electronic component of this embodiment, when the flexible push is starting to be generated, the flexible push generated on the central area of the target substrate 200 or the transfer base 300 is greater than the flexible push generated on the surrounding area, so the residual air bubbles between the target substrate 200 and the transfer substrate 300 are pushed toward the edge of the target substrate 200 or the transfer substrate 300, and then discharged from the edge. Therefore, the apparatuses 100 and 100a configured to transfer an electronic component and the method for bonding an electronic component of this embodiment can effectively remove the residual air bubbles between the target substrate 200 and the transfer substrate 300, thereby improving the process yield. In addition, as the inflator 144 continues to inflate, the even flexible push is generated on the target substrate 200 or the transfer substrate 300, so that the target substrate 200 or the transfer substrate 300 is evenly pressed, such that good and even pressing of the target substrate 200 and the transfer substrate 300 can be generated, thereby improving the manufacturing yield, and the electronic component 310 can be fixed more accurately. In this embodiment, the target substrate 200 and the transfer substrate 300 may be subjected to proper and even push by precisely controlling the air pressure of air in the air bag 142. In this way, the target substrate 200 and the transfer substrate 300 can be manufactured with a relatively large tolerance and still be evenly pressed by the flexible push, and the coplanarity requirements of the two substrates may be lowered, which can effectively reduce the manufacturing cost and the working hours of the target substrate 200 and the transfer substrate 300. In an embodiment, the air pressure of the air in the air bag 142 may be controlled at an appropriate air pressure, such as being controlled at a minimum of 0.05 kg/cm², by a precision pressure regulating valve or an air pressure proportional valve, so as to effectively control the parameters of the push.

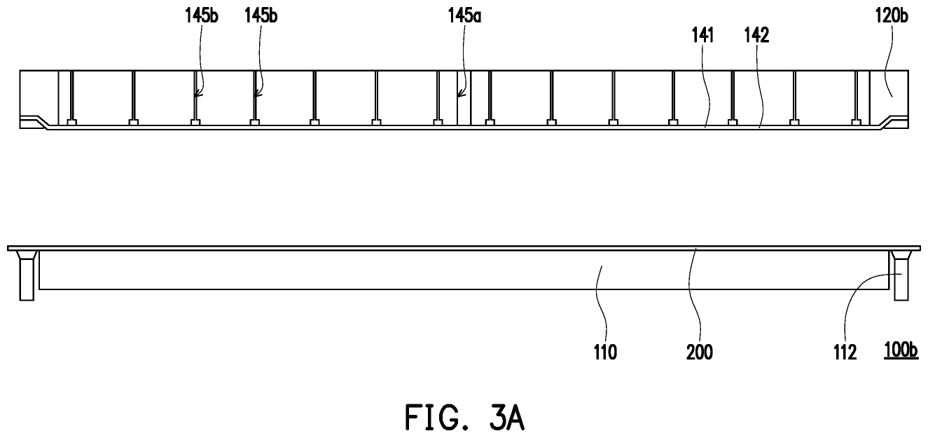

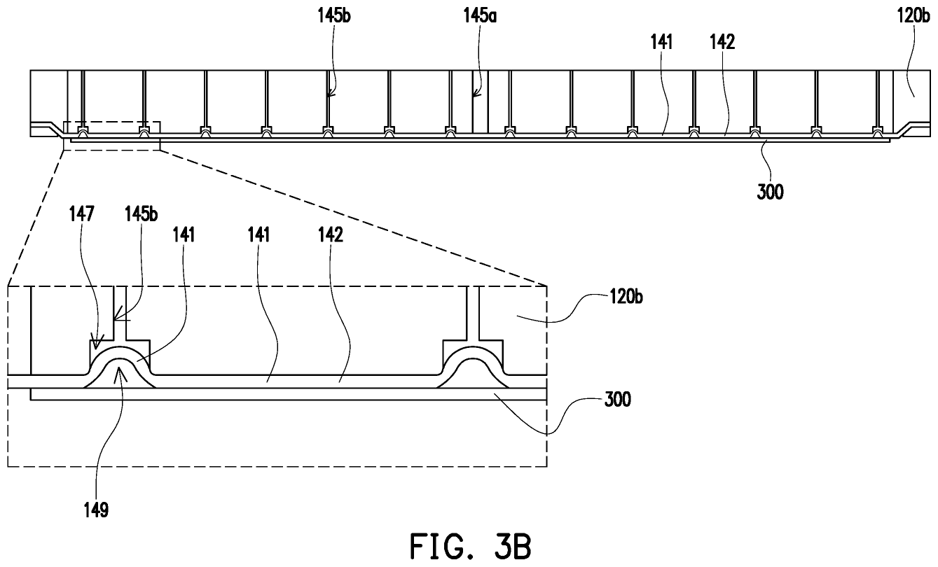

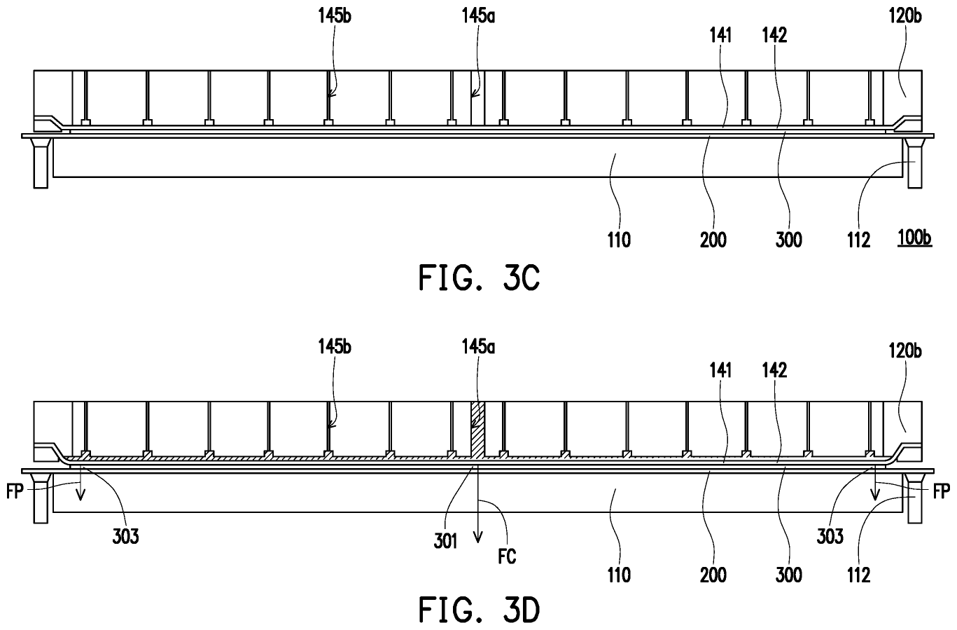

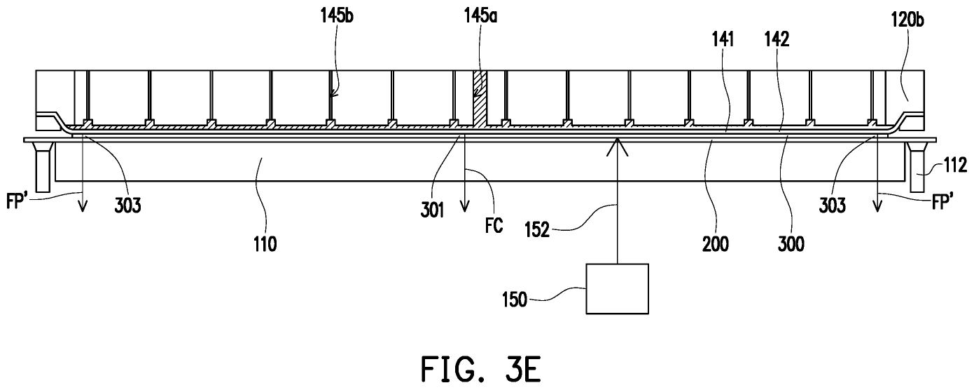

FIG. 3A to FIG. 3E are schematic cross-sectional views of an apparatus configured to transfer an electronic component in five different operating stages according to yet another embodiment of the disclosure. Please refer to FIG. 3A to FIG. 3E. An apparatus 100b configured to transfer an electronic component of this embodiment is similar to the apparatus 100a configured to transfer an electronic component of FIG. 2A to FIG. 2D, and the differences between the two are as follows. A second carrier 120b of this embodiment has a first air channel 145a and multiple second air channels 145b, and one end thereof is connected to an air suction mechanism (not shown in these drawings), and the other end is connected to a top surface of the elastic film 141. In addition, the edge of the first carrier 110 may be provided with a suction nozzle 112 to absorb the target substrate 200. In this embodiment, the target substrate 200 is, for example, a glass substrate with a thin film transistor circuit disposed on the surface of the glass substrate, but the disclosure is not limited thereto. The apparatus 100b configured to transfer an electronic component of this embodiment may be configured to execute a method for bonding an electronic component according to another embodiment of the disclosure. After the target substrate 200 is prepared as shown in FIG. 3A, the step of FIG. 3B may be performed, that is, the air suction mechanism sucks air from the second air channel 145b, so that the second carrier 120b absorbs the transfer substrate 300. At this time, a vacuum chamber 147 is generated at the lower end of the second air channel 145b to absorb the elastic film 141 and partially deform the elastic film 141. A vacuum chamber 149 is also generated between the partially deformed part of the elastic film 141 and the transfer substrate 300, so that the transfer substrate 300 is adsorbed onto the elastic film 141.

As shown in FIG. 3C, after aligning the transfer substrate 300 and the target substrate 200, the transfer substrate 300 lightly contacts the target substrate 200 and is placed on the target substrate 200 with natural gravity, and the air suction mechanism stops sucking air from the second air channel 145b. The alignment between the transfer substrate 300 and the target substrate 200 refers, for example, to that the pad 312 of the electronic component 310 on the transfer substrate 300 is aligned with the bump 210 on the target substrate 200. The details of the electronic component 310, the pad 312, and the bump 210 are not shown in FIG. 3A to FIG. 3E, and reference may be made to FIG. 2A to FIG. 2D for the graphics of the electronic component 310, the pad 312, and the bump 210.

As shown in FIG. 3D, the first air channel 145a is inflated by using the air suction mechanism, that is, the first air channel 145a is filled with positive pressure by using positive pressure air. At this time, the air bag 142 formed by the elastic film 141 and the second carrier 120b is inflated and expands, so that the elastic film 141 deforms downward to apply a flexible push to the transfer substrate 300. At this time, the second carrier 120b also slowly rises to a height, so that the transfer substrate 300 is only subjected to the flexible push applied by the air bag 142 and is not directly subjected to a contact force of the second carrier 120b.

When the air suction mechanism inflates the air bag 142 to start to generate the flexible push, the flexible push FC generated on the central area 301 of the target substrate 200 or the transfer substrate 300 (FIG. 3D is exemplified by the transfer substrate 300) is greater than the flexible push FP generated on the surrounding area 303. In this way, the residual air bubbles between the target substrate 200 and the transfer substrate 300 are pushed toward the edge of the target substrate 200 or the transfer substrate 300, and then discharged from the edge. Therefore, the apparatus 100b configured to transfer an electronic component and the method for bonding an electronic component of this embodiment can effectively remove the residual air bubbles between the transfer substrate 300 and the target substrate 200, thereby improving the process yield.

Afterwards, as shown in FIG. 3E, as the air suction mechanism continues to inflate, the flexible push FC generated on the central area 301 of the target substrate 200 or the transfer substrate 300 (FIG. 3E is exemplified by the transfer substrate 300) gradually becomes consistent with the flexible push FP′ generated on the surrounding area 303, so that the target substrate 200 and the transfer substrate 300 are evenly pressed. At this time, the laser generator 150 may be used to apply the laser beam 152 on the electronic component 310 while the air bag 142 is maintained in the inflated state, so that the electronic component 310 is detached from the transfer substrate 300 and is bonded on the bonding surface 202 of the target substrate 200. The details of bonding have been described in detail in the embodiment of FIG. 2C and will not be repeated here. In this embodiment, the laser generator 150 and the air bag 142 are disposed on two opposite sides of the transfer substrate 300, but the disclosure is not limited thereto. In the embodiment of FIG. 2C, the laser generator 150 and the air bag 142 are disposed on the same side of the transfer substrate 300.

Thereafter, air may be sucked from the second air channel 145b again by using the air suction mechanism, so that the second carrier 120b may absorb the transfer substrate 300 again, and the transfer substrate 300 may move away from the target substrate 200, such that the electronic component 310 may be detached from the transfer substrate 300 and stay on the target substrate 200.

In summary, in the apparatus configured to transfer an electronic component, the method for bonding an electronic component, and the method for manufacturing a light-emitting diode display according to the embodiments of the disclosure, when the flexible push is starting to be generated, the flexible push generated on the central area of the target substrate or the transfer substrate is greater than the flexible push generated on the surrounding area, so the residual air bubbles between the target substrate and the transfer substrate are pushed toward the edge of the target substrate or the transfer substrate, and then discharged from the edge. Therefore, the apparatus configured to transfer an electronic component, the method for bonding an electronic component, and the method for manufacturing a light-emitting diode display according to the embodiments of the disclosure can effectively remove the residual air bubbles between the target substrate and the transfer substrate, thereby improving the process yield.

What is claimed is:

1. An apparatus configured to transfer an electronic component, comprising:
a first carrier, configured to carry a target substrate;
a second carrier, configured to carry a transfer substrate;
an actuator mechanism, configured to actuate the first carrier and the second carrier to move close to and away from each other; and
a flexible push generator, disposed near the first carrier or the second carrier and applying a flexible push to the target substrate or the transfer substrate when the first carrier and the second carrier move close to each other, wherein the flexible push is in a greater magnitude onto a central portion of the target substrate or of the transfer substrate than onto a peripheral portion of the target substrate or of the transfer substrate at the start of the flexible push being applied.

2. The apparatus configured to transfer an electronic component according to claim 1, wherein the flexible push generator comprises an inflator and an air bag connected to the inflator, and the inflator inflates the air bag.

3. The apparatus configured to transfer an electronic component according to claim 1, further comprising a laser generator, disposed near the first carrier or the second carrier and generating a laser beam toward the first carrier or the second carrier.

4. A method for bonding an electronic component, comprising:
providing a transfer substrate having a carrying surface on which the electronic component to be bonded is disposed and a non-carrying surface which is opposite to the carrying surface;
providing a target substrate having a bonded surface and a non-bonded surface which is opposite to the bonded surface;
arranging the carrying surface of the transfer substrate to face the bonded surface of the target substrate;
making the transfer substrate and the target substrate approach each other until the electronic component is in contact with the bonded surface of the target substrate;
applying a flexible push to the non-carrying surface of the transfer substrate or to the non-bonded surface of the target substrate, wherein the flexible push is in a greater magnitude onto a central portion of the non-carrying surface or of the non-bonded surface than onto a peripheral portion of the non-carrying surface or of the non-bonded surface at the start of the flexible push being applied; and
applying an energy beam to bond the electronic component on the bonded surface of the target substrate from the transfer substrate.

5. The method for bonding an electronic component according to claim 4, wherein the flexible push reaches a universal magnitude gradually from the central portion to the peripheral portion of the non-carrying surface or of the non-bonded surface.

6. The method for bonding an electronic component according to claim 4, wherein the flexible push is generated by inflating an air bag.

7. The method for bonding an electronic component according to claim 4, wherein the energy beam is a laser beam.

8. The method for bonding an electronic component according to claim 4, wherein the electronic component is a light-emitting diode.

9. The method for bonding an electronic component according to claim 4, wherein the target substrate is a thin film transistor substrate.

10. A method for manufacturing a light-emitting diode display, comprising bonding a light-emitting diode using the method for bonding an electronic component according to claim 8.
